(19) United States
(12) Patent Application Publication
(10) Pub. No.: US 2010/0098890 A1
(43) Pub. Date: Apr. 22, 2010

(54) DEVICE HOUSING AND METHOD FOR MAKING THE SAME

(75) Inventors: QIN-ZHENG HOU, Shenzhen City (CN); YAN-MIN WANG, Shenzhen City (CN); GANG HUANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City, (CN); FIH (HONG KONG) LIMITED, Kowloon (HK)

(21) Appl. No.: 12/538,270

(22) Filed: Aug. 10, 2009

(30) Foreign Application Priority Data
Oct. 17, 2008 (CN) 200810304973.9

(51) Int. Cl. B32B 1/02; B32B 15/08; B05D 3/06; C23C 14/34

(52) U.S. Cl. 428/35.9; 428/35.7; 427/555; 204/192.12

(57) ABSTRACT

A device housing includes a substrate made of plastic, a base paint layer formed on the substrate surface, a vacuum coated layer formed on the base paint layer, a portion of the vacuum coated layer being textured out to form a pattern thereon, a transparent middle paint layer formed on the vacuum coated layer, and a transparent top layer formed on the middle paint layer, the top layer made of paint a having a soft tactility.

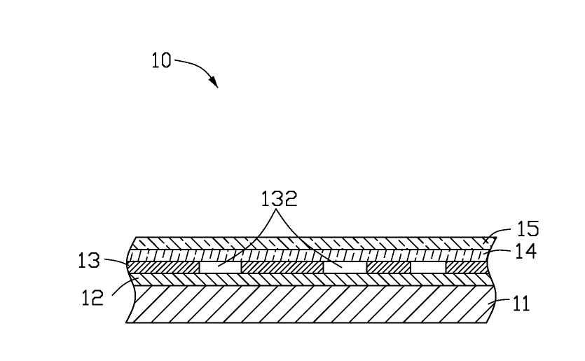

### BACKGROUND

1. Technical field

The present disclosure relates to device housings, particularly to a device housing with a soft tactility and a metallic appearance for electronic devices and a method for making the same.

2. Description of related art

Electronic devices, such as mobile telephones, personal digital assistants, and music players, enable consumers to enjoy the convenience of high technology services. These electronic devices often have decorative housings and attract consumers. Housings molded by plastic materials are usually electroplated to create a metallic appearance, since housings having metallic appearances are often more attractive for consumers.

However, an electrolyte for electroplating are sometimes poisonous and can harm the environment and human beings. The costs of waste and wastewater treatment for the electroplating process are too high.

Therefore, there is room for improvement within the art.

### BRIEF DESCRIPTION OF THE DRAWINGS

Many aspects of the device housing can be better understood with reference to the following drawing. The components in the drawing are not necessarily to scale, the emphasis instead being placed upon clearly illustrating the principles of the present device housing. Moreover, in the drawing, like reference numerals designate corresponding parts throughout the following view.

The FIGURE is a cross-section view of device housing according to an exemplary embodiment.

### DETAILED DESCRIPTION OF THE EXEMPLARY EMBODIMENTS

Referring to the FIGURE, an exemplary device housing 10 is used for mobile phones, laptop computers, cameras, or game consoles. The device housing 10 includes a plastic substrate 11, a base paint layer 12, a vacuum coated layer 13, a transparent middle paint layer 14, and a transparent top layer 15.

The base paint layer 12 is directly formed on one surface of the plastic substrate 11. The vacuum coated layer 13 has a metallic appearance and is formed on the base paint layer 12. The target for forming the vacuum coated layer 13 can be a metallic material selected from a group consisting of indium, aluminum, titanium, tin, chromium, aurum, vanadium, stainless steel, and indium-tin alloy. Alternatively the target can be a non-metallic material selected from a group consisting of titanium carbide, titanium nitride, titanium oxide, and aluminum oxide. A portion of the vacuum coated layer 13 is hollowed out to form a pattern 132. The middle paint layer 14 is formed on the vacuum coated layer 13. The middle paint layer 14 can be painted with a colorless or colored paint. Ultraviolet curing paint may be used to form the middle paint layer 14. The top layer 15 is formed on the middle paint layer 14. The top layer 15 is made of a paint having a soft tactility such acrylic lacquer, or polyurethane lacquer.

An exemplary method for making the device housing 10 may include the following steps.

A plastic substrate 11 is provided. The plastic substrate 11 can be molded by plastic such as polycarbonate (PC), polyethylene (PE), polymethyl methacrylate (PMMA), etc.

A base paint layer 12 is formed on one surface of the plastic substrate 11 for example, by painting. The base paint layer 12 can improve the smoothness of the surface of the plastic substrate 11, accordingly, the subsequently formed vacuum coated layer 13 can present a glossy appearance. Moreover, the base paint layer 12 may improve the adhesion for bonding with the subsequent vacuum coated layer 13.

A vacuum coated layer 13 with a metallic appearance is formed on the base paint layer 12 by implementing a vacuum coating method such as vacuum evaporating, or sputtering. The target used to form the vacuum coated layer 13 can be metallic material or non-metallic material. The non-metallic material should have a metallic appearance. The metallic material can be selected from a group consisting of indium, aluminum, titanium, tin, chromium, aurum, vanadium, stainless steel and indium-tin alloy. The non-metallic material can be selected from a group consisting of titanium carbide, titanium nitride, titanium oxide, and aluminum oxide. When the device housing 10 is used for a communication device (e.g., mobile phone), the vacuum coated layer 13 can be nonconductive by choosing a non-conductive target material and controlling the thickness of the vacuum coated layer 13 in a proper range.

A transparent middle paint layer 14 is formed on the vacuum coated layer 13. The middle paint layer 14 can be colorless or include different colored dyes therein. The material of the middle paint layer 14 may be ultraviolet curing paint. The middle paint layer 14 can protect the vacuum coated layer and improve the adhesive force for the subsequent top layer 15.

A pattern 132 is formed on the vacuum coated layer 13 by means of for example, laser etching. In this step, a laser source is provided. The laser emitted by the laser source irradiate on the middle paint layer 14 surface along a path according to the pattern 132. Because the middle paint layer 14 is transparent and cannot absorb any light energy, the laser can penetrate through the middle paint layer 14 and focus on the vacuum coated layer 13. The laser etches the vacuum coated layer 13, thereby a portion of the vacuum coated layer 13 is etched throughout by the laser to form the pattern 132.

A transparent top layer 15 is formed on the middle paint layer 14 e.g., by painting. The top layer 15 is made of a paint having a soft tactility such as acrylic lacquer, or polyurethane lacquer.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1 A device housing, comprising:
a substrate, the substrate being made of plastic;
a base paint layer formed on one surface of the substrate;
a vacuum coated layer formed on the base paint layer, a portion of the vacuum coated layer being hollowed out to form a pattern thereon;
a transparent middle paint layer formed on the vacuum coated layer; and
a transparent top layer formed on the middle paint layer, the top layer being made of paint having a soft tactility.

2. The device housing as claimed in claim 1, wherein the target for forming the vacuum coated layer is a metallic material.

3. The device housing as claimed in claim 2, wherein the metallic material is selected from a group consisting of indium, aluminum, titanium, tin, chromium, aurum, vanadium, stainless steel and indium-tin alloy.

4. The device housing as claimed in claim 1, wherein the target for forming the vacuum coated layer is a non-metallic material.

5. The device housing as claimed in claim 4, wherein the non-metallic material is selected from a group consisting of titanium carbide, titanium nitride, titanium oxide, and aluminum oxide.

6. The device housing as claimed in claim 1, wherein the middle paint layer is painted with a colorless or colored ultraviolet curing paint.

7. The device housing as claimed in claim 1, wherein the top layer is made of acrylic lacquer or polyurethane lacquer.

8. A method for making a device housing, comprising the steps of:
providing a substrate made of plastic;
forming a base paint layer on the substrate;
forming a vacuum coated layer on the base paint layer;
forming a middle paint layer on the vacuum coated layer;
etching throughout a portion of the vacuum coated layer by laser to form a pattern thereon; and
forming a transparent top layer on the middle paint layer, the top layer made of a paint having soft tactility.

9. The method for making a device housing as claimed in claim 8, wherein a laser source emitting laser is used to form the pattern.

10. The method for making a device housing as claimed in claim 9, wherein the laser penetrates the middle paint layer and focus on the vacuum coated layer.

11. The method for making a device housing as claimed in claim 8, wherein the vacuum coated layer is formed by vacuum evaporating or vacuum sputtering.

12. The method for making a device housing as claimed in claim 8, wherein the target for forming the vacuum coated layer is a metallic material.

13. The method for making a device housing as claimed in claim 12, wherein the metallic material is selected from indium, aluminum, titanium, tin, chromium, aurum, vanadium, stainless steel and indium-tin alloy.

14. The method for making a device housing as claimed in claim 8, wherein the target for forming the vacuum coated layer is a metallic material.

15. The method for making a device housing as claimed in claim 14, wherein the metallic material is selected from titanium carbide, titanium nitride, titanium oxide, and aluminum oxide.

16. The method for making a device housing as claimed in claim 8, wherein the middle paint layer is painted with a colorless or colored ultraviolet curing paint.

17. The method for making a device housing as claimed in claim 8, wherein the top layer is made of acrylic lacquer or polyurethane lacquer.
